(19) United States
(12) Patent Application Publication
(10) Pub. No.: US 2015/0041971 A1
(43) Pub. Date: Feb. 12, 2015

(54) STACKED SEMICONDUCTOR APPARATUS

(71) Applicant: SK hynix Inc., Icheon-si (KR)

(72) Inventor: Chang Hyun LEE, Icheon-si (KR)

(73) Assignee: SK hynix Inc., Icheon-si (KR)

(21) Appl. No.: 14/092,382

(22) Filed: Nov. 27, 2013

(30) Foreign Application Priority Data
Aug. 9, 2013 (KR) 10-2013-0094578

(51) Int. Cl. H01L 23/00

(52) U.S. Cl. CPC H01L 24/10
USPC 257/737

(57) ABSTRACT

A stacked semiconductor apparatus includes a main die, a plurality of slave dies, and a vertical interposer. The vertical interposer is vertically stacked on the main die.

### CROSS-REFERENCES TO RELATED APPLICATION

The present application claims priority under 35 U.S.C. §119(a) to Korean application number 10-2013-0094578, filed on Aug. 9, 2013, in the Korean Intellectual Property Office, which is incorporated herein by reference in its entirety as set forth in full.

### BACKGROUND

1. Technical Field

Various embodiments relate to a semiconductor apparatus, and more particularly, to a stacked semiconductor apparatus.

2. Related Art

In order to elevate the degree of integration of a semiconductor apparatus, a stacked semiconductor apparatus has been developed in which a plurality of chips are stacked and packaged in a single package. Recently, a TSV (through-silicon via) type semiconductor apparatus has been disclosed in the art, in which silicon vias are formed through a plurality of stacked chips so that all the chips of the stack are electrically coupled with one another.

FIG. 1 is a diagram schematically illustrating the configuration of a stacked semiconductor apparatus 10 according to the conventional art. In FIG. 1, the stacked semiconductor apparatus 10 includes an interposer 11 and a plurality of dies 12. The plurality of dies 12 are electrically coupled with one another through vias 13 formed through the plurality of dies 12. The through vias 13 may be electrically coupled with the interposer 11 through bumps 14. Consequently, the interposer 11 is able to input signals to the respective dies 12 through the through vias 13, and to receive signals, which are outputted from the respective dies 12, through the through vias 13.

Because a through via, such as a through-silicon via, is filled with a conductive material, through vias have resistor and capacitor characteristics. Accordingly, when signals are transmitted through the through via, resistor-capacitor (RC) delay inevitably occurs. For example, when a clock signal is transmitted to the plurality of dies 12 from the interposer 11, a significant skew may occur between a time point at which a first stacked die receives the clock signal and a time point at which a last stacked die receives the clock signal. Such a skew causes a significant limitation to the operational performance of a conventionally stacked semiconductor apparatus that operates in synchronization with a clock signal.

Furthermore, a semiconductor apparatus such as memory may process mass storage data. In the stacked semiconductor apparatus, the data is transmitted through the through vias, resulting in an increase in the number of through vias required for inputting/outputting the mass storage data. However, die 12 area is limited. Thus, the number of through vias which can be formed through the dies 12 is also limited. The limitation in the die area also causes a limitation in bandwidth of the semiconductor apparatus.

### SUMMARY

A stacked semiconductor apparatus including an interposer vertically formed is described herein.

In an embodiment, a stacked semiconductor apparatus includes: a main die; a plurality of slave dies stacked on the main die such that each slave die is parallel to the main die; and a vertical interposer vertically stacked on the main die.

In an embodiment, a stacked semiconductor apparatus includes: a main die; a plurality of slave dies sequentially stacked on the main die such that each slave die is parallel to the main die; and a vertical interposer vertically stacked on the main die, and surrounding two or more surfaces of each of the plurality of stacked slave dies.

In an embodiment, a stacked semiconductor apparatus includes: a main die, a plurality of slave dies stacked on the main die such that at least one of a top and/or bottom of each slave die is parallel to at least one of a top or bottom of the main die, and a vertical interposer vertically stacked on the main die, such that one of a top or bottom of the vertical interposer may be substantially parallel to a side of each slave die.

### BRIEF DESCRIPTION OF THE DRAWINGS

Features, aspects, and embodiments are described in conjunction with the attached drawings, in which:

FIG. 1 is a diagram schematically illustrating a configuration of a stacked semiconductor apparatus according to the conventional art;

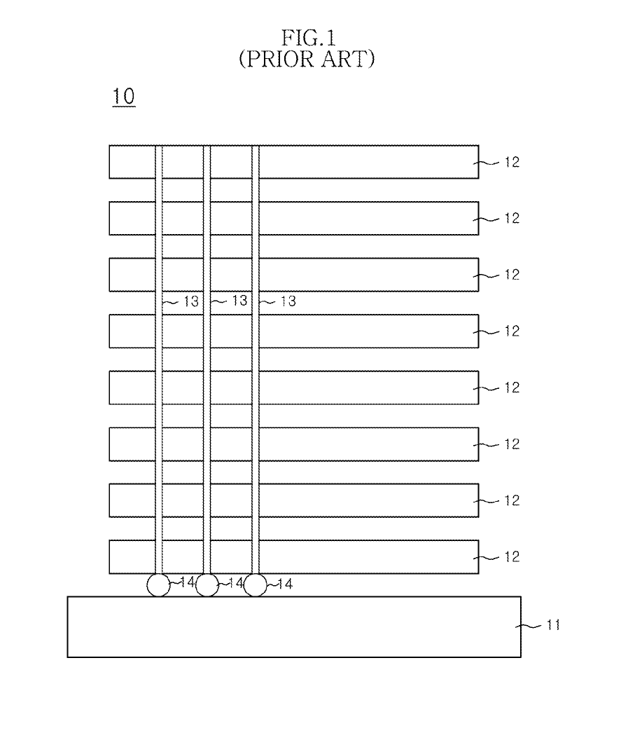

FIG. 2 is a diagram illustrating a configuration of a stacked semiconductor apparatus according to an embodiment;

FIG. 3 is a diagram illustrating a configuration of a stacked semiconductor apparatus according to an embodiment; and

FIG. 4 is a diagram illustrating a configuration of a stacked semiconductor apparatus according to an embodiment.

FIG. 5 is a diagram illustrating a memory system including embodiments of a stacked semiconductor apparatus.

### DETAILED DESCRIPTION

Hereinafter, a stacked semiconductor apparatus according to embodiments of the present invention will be described in detail with reference to the accompanying drawings through example embodiments.

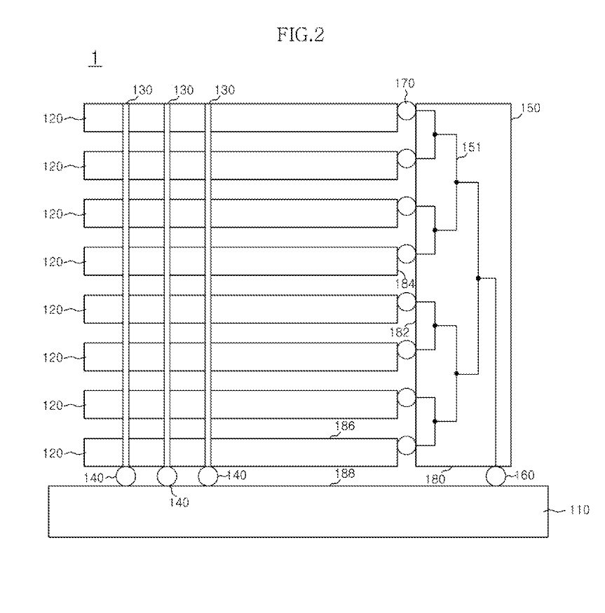

In FIG. 2, a stacked semiconductor apparatus 1 may include a plurality of dies. In an embodiment, a die capable of communicating with each of the plurality of stacked dies is called a main die. Dies, which communicate with the main die and do not communicate with one another, are called slave dies. The stacked semiconductor apparatus 1 may include one or more main dies and two or more slave dies. FIG. 2 illustrates a semiconductor apparatus in which one main die and 8 slave dies are stacked. The main die 110 may be at least one of an interposer chip, a controller chip, and a processor chip. The slave die 120 may be a memory chip. The semiconductor apparatus 1 may be packaged in a single package configured as a system on chip (SoC) or a system in package (SiP).

In FIG. 2, the plurality of slave dies 120 are stacked on the main die 110. The plurality of slave dies 120 may be sequentially stacked in parallel to the main die 110. That is, the plurality of slave dies 120 may be stacked such that a top and/or bottom of each slave die 120 may be substantially parallel to a top and/or bottom of the main die 110. A size of the main die 110 may be different than a size of each of the slave dies 120. In one example, the main die 110 may be larger than each of the slave dies 120. FIG. 2 illustrates that the main die 110 is stacked underneath the plurality of slave dies 120. However, the present invention is not limited thereto. The main die 110 may be stacked among the plurality of slave dies 120, or may be stacked on top of the plurality of slave dies 120. The stacked semiconductor apparatus 1 may include a plurality of through vias 130, wherein the through vias 130 are formed through the plurality of slave dies 120. One end of each through via 130 may be electrically coupled with the main die 110 through a bump 140. Consequently, the main die 110 and the plurality of slave dies 120 may be electrically coupled with each other through the through vias 130.

The stacked semiconductor apparatus 1 may include a vertical interposer 150. The vertical interposer 150 may be vertically stacked on the main die 110. The vertical interposer 150 and the slave dies 120 may be formed on or over one surface of the main die 110. In one embodiment, the vertical interposer 150 is not stacked on, above, or within the plurality of slave dies 120. When the vertical interposer 150 is vertically stacked, the vertical interposer 150 may be oriented on a side 180 such that a top and/or bottom 182 of the vertical interposer 150 may be substantially parallel to a side 184 of each slave die 110. Further the top and/or bottom 182 of the vertical interposer 150 may be substantially perpendicular to a top and/or bottom 188 of the main die 110. The top and/or bottom 182 of the vertical interposer 150 may be substantially perpendicular to a top and/or bottom 186 of each of the slave dies 120. In one embodiment, the top and/or bottom 182 of the vertical interposer 150 may extend to a height that is substantially equal to a height of the plurality of stacked slave dies 120. The vertical interposer 150 may be electrically coupled with the main die 110 through at least one bump 160, and may be electrically coupled with the plurality of slave dies 120 through one or more other bumps 170. Further, in one embodiment, both the vertical interposer 150 and the plurality of slave dies 120 may be stacked on top 188 of the main die 110.

The vertical interposer 150 may be an interface chip that relays communication between the main die 110 and the plurality of slave dies 120. The vertical interposer 150 may transmit a signal received from the main die 110 to each of the plurality of slave dies 120, and transmit a signal outputted from each of the plurality of slave dies 120 to the main die 110. For example, the vertical interposer 150 may transmit a clock signal received from the main die 110 to each of the plurality of slave dies 120. Since memory typically operates in synchronization with a clock signal, it is preferable that input time points of the clock signal to the stacked memories are substantially equal to one another. When the clock signal is inputted to each of the plurality of slave dies 120 through the through vias 130, a skew inevitably occurs between a time point at which a slave die directly stacked on the main die 110 receives the clock signal and a time point at which a slave die stacked at the uppermost end of the stack of slave dies 120 receives the clock signal. In order that the stacked semiconductor apparatus 1 performs optimally, it is important that the slave dies 120 start to operate at substantially the same time point, and the slave dies 120 should be able to output data regardless of a stacked position or order.

The stacked semiconductor apparatus 1 according to an embodiment includes the vertical interposer 150 and allows the clock signal to be inputted to the stacked slave dies 120 at substantially the same time point such that each slave die 120 of the stacked slave dies 120 may operate based on a clock signal received at substantially the same time point without any skew. In an embodiment, the signal transmitted by the vertical interposer 150 is the clock signal. However, the present invention is not limited thereto. Any type of signals, including data, communicated between the main die 110 and the slave dies 120 may be transmitted through the vertical interposer 150. The vertical interposer 150 may include signal paths 151 through which a signal inputted from the main die 110 may be transmitted. The lengths of the signal paths 151 from the main die 110 to the slave dies 120 may be formed to be substantially equal to one another. As illustrated in FIG. 2, the signal paths 151 may be formed in a tree shape. The bump 160 may serve as a connection point between the main die 110 and the vertical interposer. Each bump 170 may serve as a connection point between the vertical interposer 150 and at least one slave die 120. The lengths of the signal paths from the bump 160 to each of the bumps 170 may be substantially equal. Thus, there may be a substantially equal signal path 151 length from the connection point with the main die 110 and each connection point with each slave die 120.

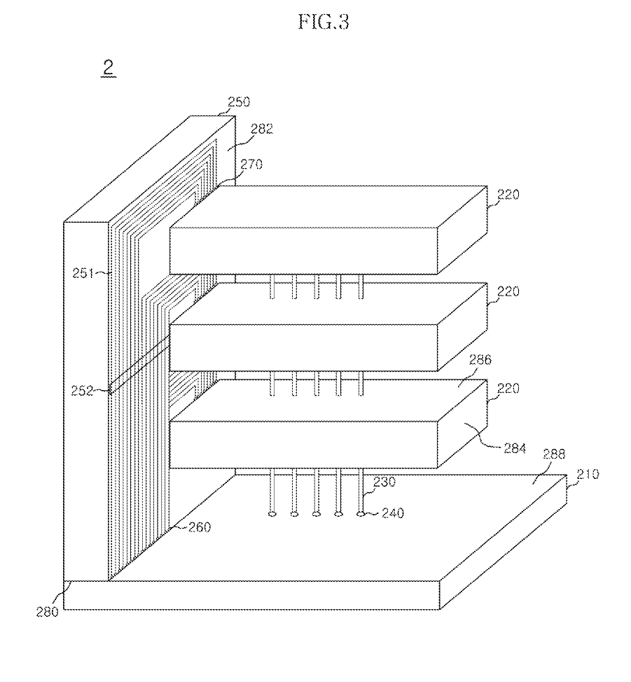

FIG. 3 is a diagram illustrating a configuration of a stacked semiconductor apparatus 2 according to an embodiment. FIG. 3 illustrates a stacked semiconductor apparatus 2 in which one main die and three slave dies are stacked. The slave dies 220 are horizontally oriented and stacked on the main die 210. A size of the main die 210 may be different than a size of each of the slave dies 220. In one example, the main die 210 may be larger than each of the slave dies 220. The stacked semiconductor apparatus 2 may include a plurality of through vias 230, wherein the through vias 230 are formed through the plurality of slave dies 220. One end of each through via 230 may be electrically coupled with the main die 210 through a bump 240. Consequently, the main die 210 and the slave dies 220 may be electrically coupled with each other through the through vias 230.

The stacked semiconductor apparatus 2 may include a vertical interposer 250 that is vertically stacked on the main die 210. When the vertical interposer 250 is vertically stacked, the vertical interposer 250 may be oriented on a side 280 such that a top and/or bottom 282 of the vertical interposer 250 may be substantially parallel to a side 284 of each slave die 220. Further the top and/or bottom 282 of the vertical interposer 250 may be substantially perpendicular to a top and/or bottom 286 of each slave die 220. The top and/or bottom of the vertical interposer 250 may be substantially perpendicular to a top and/or bottom 288 of the main die 210. In one embodiment, the top and/or bottom 282 of the vertical interposer 250 may extend to a height that is substantially equal to or greater than a height of the plurality of stacked slave dies 220. The vertical interposer 250 and the slave die 220 may be formed on or over one surface of the main die 210. The vertical interposer 250 may be electrically coupled with the main die 210 through bumps 260. The vertical interposer 250 may be electrically coupled with the plurality of slave dies 220 through other bumps 270. The vertical interposer 250 may be formed at at least one edge the main die 210 such that at least one surface of the vertical interposer 250 is substantially even with at least one surface of the main die 210 to form a single plane. The vertical interposer 250 may be an interface chip that relays communication between the main die 210 and the slave dies 220.

The vertical interposer 250 may include a plurality of data transmission lines 251. The vertical interposer 250 may transmit data received from the main die 210 to each of the plurality of slave dies 220. The vertical interposer 250 may transmit data outputted from each of the plurality of slave dies 220 to the main die 210. Since a memory apparatus inputs/outputs mass storage data, a plurality of data transmission lines or channels are typically used between a memory and a controller or a processor. A stacked semiconductor apparatus such as a system on chip or a system in package utilizes a through via as the data transmission line. However, there is a limitation in the area of a stacked die, resulting in a limitation of the number of the through vias which can be formed in the stacked semiconductor apparatus. In this regard, the stacked semiconductor apparatus 2, according to an embodiment, includes the vertical interposer 250, and the stacked semiconductor apparatus 2 is configured to include the data transmission lines 251 formed in the vertical interposer 250. Thus, the data transmission lines 251 may be used with or in lieu of the through vias 230 to transfer data to/from the main die 210 to the slave dies 220. Consequently, it is possible to reduce the number of through vias for data transmission and to significantly increase bandwidth of the stacked semiconductor apparatus.

The vertical interposer 250 of the stacked semiconductor apparatus 2 may further include a plurality of repeaters 252. The plurality of repeaters 252 may be arranged among the data transmission lines 251 to drive the data transmission lines 251. The repeaters 252 may drive the data transmission lines 251 such that data can be transmitted more reliably.

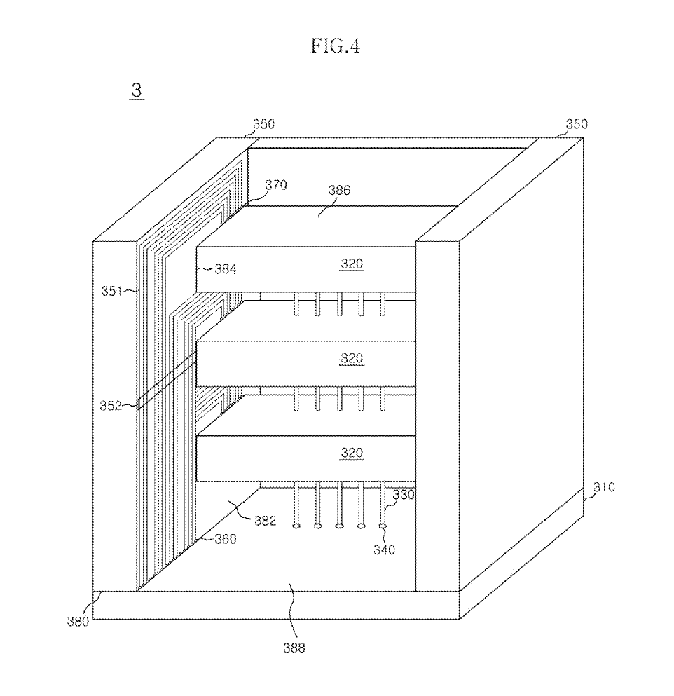

FIG. 4 is a diagram illustrating a configuration of a stacked semiconductor apparatus 3 according to an embodiment. In FIG. 4, the stacked semiconductor apparatus 3 may include a main die 310, a plurality of slave dies 320, and a vertical interposer 350. The plurality of slave dies 320 may be stacked on the main die 310. A size of the main die 310 may be different than a size of each of the slave dies 320. In one example, the main die 310 may be larger than each of the slave dies 320. When stacked on the main die 310, the plurality of slave dies 320 may be oriented such that each slave die is substantially parallel to the main die 310. In other words, a top and/or bottom 386 of each slave die 320 may be substantially parallel with a top and/or bottom 388 of the main die 310. The stacked semiconductor apparatus 3 may include a plurality of through vias 330, wherein the through vias 330 are formed through the plurality of slave dies 320. One end of each through via 330 is electrically coupled with the main die 310 through a bump 340. Consequently, the main die 310 and the plurality of slave dies 320 may be electrically coupled with each other through the through vias 330.

The vertical interposer 350 is vertically stacked on the main die 310. When the vertical interposer 350 is vertically stacked, the vertical interposer 350 may be oriented on a side 380 such that a top and/or bottom 382 of the vertical interposer 350 may be substantially parallel to a side 384 of each slave die 320. Further the top and/or bottom 382 of the vertical interposer 350 may be substantially perpendicular to a top and/or bottom 386 of each slave die 320. In one embodiment, the top and/or bottom 382 of the vertical interposer 350 may extend to a height that is substantially equal or greater than a height of the plurality of stacked slave dies 320. The vertical interposer 350 and the slave dies 320 may be formed on or over one surface of the main die 310. The vertical interposer 350 may be formed to surround two or more sides of each stacked slave die 320. FIG. 4 illustrates the vertical interposer 350 as surrounding three surfaces of each stacked slave die 320. The vertical interposer 350 may be formed at at least one edge the main die 310 such that at least one surface of the vertical interposer 350 is substantially even with at least one surface of the main die 310 to form a single plane. However, the vertical interposer 350 may surround four surfaces of each stacked slave die 320. That is, the vertical interposer 350 may have a structure of a signal path wall. The vertical interposer 350 may include a plurality of data transmission lines 351 that electrically couple the main die 310 to the slave dies 320. Because the vertical interposer 350 should be able to accommodate many data transmission lines 351, when the vertical interposer 350 is formed to surround several surfaces of each stacked slave die 320, the large available surface area of the vertical interposer 350 allows for more space where data transmission lines can be arranged. Since it is possible to form other signal transmission lines as well as the data transmission lines 351, it is possible to reduce the number of the through vias 330 formed through the slave dies 320, and to significantly reduce the surface area of each slave die 320.

Furthermore, as well as the aforementioned signal lines, several circuits required for performing communication between the main die 310 and the slave dies 320 may be formed in the vertical interposer 350. That is, the vertical interposer 350 may include some of the circuits constituting the slave dies 320 as well as circuits constituting the main die 310. When the circuits constituting the main die 310 and the slave dies 320 are formed in the vertical interposer 350, it is possible to decrease the area of the dies 310 and 320, and to further optimize the operational performance of the stacked semiconductor apparatus 3.

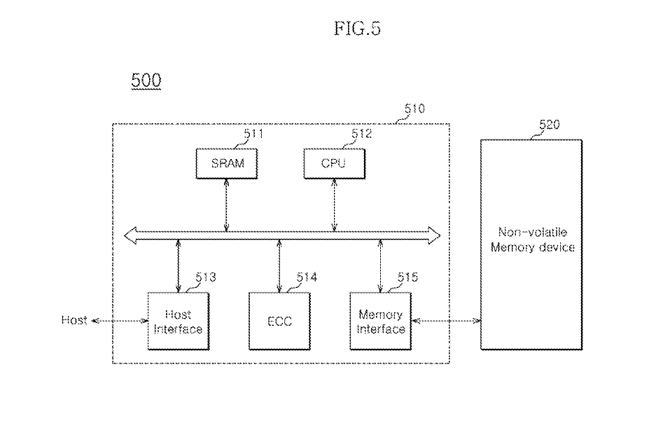

FIG. 5 illustrates a memory system that may include embodiments of a stacked semiconductor apparatus disclosed herein. In FIG. 5, the memory system 500 of the present embodiment may include a non-volatile memory device 520 and a memory controller 510.

The non-volatile memory device 520 may have the structure described above. The non-volatile memory device 520 may be a multi-chip package having flash memory chips.

The memory controller 510 controls the non-volatile memory device 520, and may include an SRAM 511, a CPU 512, a host interface 513, an ECC 514 and a memory interface 515. The SRAM 511 is used as an operation memory of the CPU 512, the CPU 512 performs control operation for data exchange of the memory controller 510, and the host interface 513 has data exchange protocol of a host accessed to the memory system 500. The ECC 514 detects and corrects error of data read from the non-volatile memory device 520, and the memory interface 515 interfaces with the non-volatile memory device 520. The memory controller 510 may include further ROM for storing data for interfacing with the host, etc.

The memory system 500 may be used as a memory card or a solid state disk SSD by combination of the non-volatile memory device 520 and the memory controller 510. In the event that the memory system 500 is the SSD, the memory controller 510 communicates with an external device, e.g. host through one of various interface protocols such as USB, MMC, PCI-E, SATA, PATA, SCSI, ESDI, IDE, etc.

Various semiconductor systems may include embodiments of the stacked semiconductor apparatus disclosed herein. The various semiconductor systems may include a Central Processing Unit, a Graphic Processing Unit, a Digital Signal Processor, Multiple Core Processor, a plurality of Processors or controllers, an Integrated Circuit or an Application-Specific Integrated Circuit, and system or device which includes the above described.

While certain embodiments have been described above, it will be understood to those skilled in the art that the embodiments described are by way of example only. Accordingly, the stacked semiconductor apparatus described herein should not be limited based on the described embodiments. Rather, the stacked semiconductor apparatus described herein should only be limited in light of the claims that follow when taken in conjunction with the above description and accompanying drawings.

What is claimed is:

1. A stacked semiconductor apparatus comprising:
a main die;
a plurality of slave dies stacked on the main die such that each slave die is parallel to the main die; and
a vertical interposer vertically stacked on the main die.

2. The stacked semiconductor apparatus according to claim 1, wherein the vertical interposer is electrically coupled with each of the plurality of slave dies through a bump.

3. The stacked semiconductor apparatus according to claim 1, wherein the vertical interposer is electrically coupled with the main die through a bump.

4. The stacked semiconductor apparatus according to claim 1, wherein the vertical interposer receives a signal from the main die and transmits the signal to each of the plurality of slave dies.

5. The stacked semiconductor apparatus according to claim 1, wherein the vertical interposer comprises:
signal paths that electrically couple the main die to each of the plurality of slave dies such that a signal inputted from the main die is transmitted to each of the plurality of slave dies,
wherein lengths of the signal paths are substantially equal to one another.

6. The stacked semiconductor apparatus according to claim 1, wherein the vertical interposer comprises:
a plurality of data transmission lines that electrically couple the main die to the plurality of slave dies.

7. The stacked semiconductor apparatus according to claim 6, wherein the vertical interposer further comprises:
a repeater that drives the plurality of data transmission lines.

8. A stacked semiconductor apparatus
a main die;
a plurality of slave dies sequentially stacked on the main die such that each slave die is parallel to the main die; and
a vertical interposer vertically stacked on the main die, and surrounding two or more surfaces of each of the plurality of stacked slave dies.

9. The stacked semiconductor apparatus according to claim 8, wherein the vertical interposer is electrically coupled with each of the plurality of slave dies through a bump.

10. The stacked semiconductor apparatus according to claim 8, wherein the vertical interposer is electrically coupled with the main die through a bump.

11. The stacked semiconductor apparatus according to claim 8, wherein the vertical interposer comprises:
a plurality of data transmission lines that electrically couple the main die to the plurality of slave dies.

12. The stacked semiconductor apparatus according to claim 11, wherein the vertical interposer further comprises:
a repeater that drives the plurality of data transmission lines.

13. A stacked semiconductor apparatus comprising:
a main die;
a plurality of slave dies stacked on the main die such that at least one of a top or bottom of each slave die is parallel to at least one surface of the main die; and
a vertical interposer vertically stacked on the main die, such that at least one of a top or bottom of the vertical interposer may be substantially parallel to at least one of a side of each slave die.

14. The stacked semiconductor apparatus according to claim 13, wherein the vertical interposer comprises:
signal paths that electrically couple the main die to each of the plurality of slave dies, wherein
wherein lengths of the signal paths are substantially equal to one another.

15. The stacked semiconductor apparatus of claim 13, wherein the vertical interposer and the slave dies are formed over one surface of the main die.

16. The stacked semiconductor apparatus of claim 13, wherein a size of the main die is different than a size of the slave die.

17. The stacked semiconductor apparatus of claim 13, wherein each of the slave dies comprises a memory chip, and the main die comprises at least one of an interposer chip, a controller chip, or a processor chip.

18. The stacked semiconductor apparatus of claim 13, wherein the vertical interposer is formed at least one edge of the main die such that at least one surface of the vertical interposer is substantially even with at least one surface of the main die to form a single plane.

19. The stacked semiconductor apparatus according to claim 13, wherein the vertical interposer receives a signal from the main die and transmits the signal to each of the plurality of slave dies.

20. The stacked semiconductor apparatus according to claim 13, wherein the vertical interposer is electrically coupled with the main die through a bump.
